(19) United States
(12) Patent Application Publication
(10) Pub. No.: US 2018/0076280 A1
(43) Pub. Date: Mar. 15, 2018

(54) SHALLOW DRAIN METAL-OXIDE-SEMICONDUCTOR TRANSISTORS

(71) Applicant: Jeng-Jye Shau, Palo Alto, CA (US)

(72) Inventor: Jeng-Jye Shau, Palo Alto, CA (US)

(73) Assignee: Jeng-Jye Shau, Palo Alto, CA (US)

(21) Appl. No.: 15/262,356

(22) Filed: Sep. 12, 2016

(51) Int. Cl. H01L 29/06; H01L 29/08; H01L 29/10

(52) U.S. Cl. CPC H01L 29/0646; H01L 29/0653; H01L 29/78; H01L 29/1033; H01L 29/0847

(57) ABSTRACT

Shallow drain MOS transistors provide solutions to overcome the short channel effects of Metal-Oxide-Semiconductor (MOS) transistors. Instead of reducing channel depth, the short channel effects of Metal-Oxide-Semiconductor (MOS) transistors, especially drain voltage induced leakage currents, can be overcome by reducing effective drain depth. Shallow drain MOS transistors can be manufactured using integrated circuit technologies developed for planar MOS transistors. An optional under-drain insulator layer also can be used to reduce parasitic capacitances for performance improvements.

### BACKGROUND OF THE INVENTION

The present invention relates to Metal-Oxide-Semiconductor (MOS) transistors, and more particularly to short channel MOS transistors.

MOS transistors are core devices of Integrated Circuits (IC), and channel length (L) is one of the most critical parameters of MOS transistors. As IC technologies advanced, the channel lengths of MOS transistors were reduced to increase both the operation speed and the number of components per chip. However, as the channel lengths of MOS transistors decreased, “short channel effects” caused significant problems. One of the most troublesome short channel effects is the Drain Voltage Induced Leakage (DVIL) problem.

The prior art examples shown in FIGS. 1(a-f) illustrate critical structures that cause DVIL problems. The dimensions in these and other figures used in this patent application are not necessarily drawn to scale because many critical structures would be difficult to view if they are drawn to scale. FIG. 1(a) is a symbolic cross-section view that shows a gate insulator (100) formed on the surface of a semiconductor substrate (109). The semiconductor Substrate (109) in this and all the following examples in this patent application can be a silicon substrate, a germanium substrate, or a substrate formed of other semiconductor materials. This semiconductor Substrate (109) can be part of a common wafer, part of a semiconductor-on-insulator (SOI) wafer, part of a semiconductor fin that is grown above field insulator, or a semiconductor body shaped in other forms that is used to support gate insulator on the surface. The materials for gate insulator can be SᵢO₂, Al₂O₃, HfAlO, HfAlON, AlZrO, HfSᵢOₓ, HfSᵢON, LaAlO₃, ZrO₂, or other insulator materials. The gate insulator (100) is covered by a gate conductor (101), which can be polysilicon or other conductor materials. The surface dimension of the gate insulator defines the channel length (L), as illustrated in FIG. 1(a). In this example, the active area is surrounded by field insulators (107) that provide electrical isolations from other electrical components. Current art field insulators (107) are typically formed by Shallow Trench Isolation (STI).

FIG. 1(b) shows the symbolic cross-section view after the dopants for the diffusion region (111) of lightly-doped-drain (LDD) have been implanted. This process is self-aligned because boundaries of the LDD implant (111) areas are defined by the field insulators (107) and the gate electrode (101) so that there is no need to use an additional masking step. The next step is to place gate spacers (103) on both sides of the gate conductor (101), as shown by the symbolic cross-section view in FIG. 1(c). At this time, the LDD implant (111) diffuses into the channel region due to thermal treatments, so that the effective channel length (Le) of the transistor is shorter than the geometric channel length (L), as shown in FIG. 1(c).

For prior art technologies, the next step is self-aligned implantation for the heavily doped drain diffusion region (113) using the boundaries defined by the gate spacers (103) and the field insulators (107), as shown in FIG. 1(d). FIG. 1(e) shows the symbolic cross-section view after the structure in FIG. 1(d) went through thermal annealing. At this time, the heavily doped drain diffusion regions (113) expand into the area under the gate spacers (103), as shown in FIG. 1(e).

A number of terms are defined to facilitate descriptions of critical structures that influence drain voltage induced leakage. The channel region of a MOS transistor is defined as the region in the semiconductor substrate that is under the gate insulator of the MOS transistor. The channel depth (Dg) of a MOS transistor is defined as the depth of the semiconductor substrate under the gate insulator of the MOS transistor. For planar MOS transistors, such as the example in FIG. 1(e), Dg is much larger than the channel length of the transistor. The effective drain depth (Dd) of a MOS transistor is defined as the maximum depth of the “critical drain diffusion region” (CDD) of the MOS transistor. By definition, CDD includes the drain diffusion region or drain diffusion regions in the semiconductor substrate that are no more than one channel length away from the edge of the channel region of the MOS transistor. By definition, a “drain diffusion region” is a diffusion region that is electrically connected to the drain terminal of a MOS transistor through a low impedance electrical connection. Because of the symmetry between source and drain terminals of MOS transistors, most of the terms defined for the drain are also applicable for the source. For example, we also call the diffusion region that is electrically connected to the source terminal of a MOS transistor through a low impedance electrical connection as the “drain diffusion region”, and the definition of CDD is also applicable to the source side of MOS transistors. For the example in FIG. 1(e), CDD includes the drain diffusion regions (111, 113) to the right of the channel region (165) and to the left of the dash line that is marked as “CDD boundary”, which is one channel length (L) from the edge of the channel region (165). CDD represents the drain diffusion region or drain diffusion regions that are potentially critical to drain voltage induced leakage. For the example in FIG. 1(e), the effective drain depth (Dd) is equal to the depth of the heavily doped drain diffusion (113). By definition in this patent application, the “Drain Voltage Influenced Region” (DVIR) is equivalent to the depletion region(s) around the drain of a MOS transistor when the gate terminal of the transistor is biased at flat-band voltage. DVIR defined in this way represents the regions in the semiconductor substrate that are influenced by drain voltage. Similarly, the “Source Voltage Influenced Region” (SVIR) is equivalent to the depletion region(s) around the source terminal of a MOS transistor when the gate terminal of the transistor is biased at flat-band voltage. SVIR defined in this way represents the regions in the semiconductor substrate that are influenced by source voltage. The term “off-state bias condition”, by definition, is the condition when the source, gate, and substrate terminals of an MOS transistor are all connected to the same voltage, while the drain-to-source voltage difference is at the standard operation voltage supported by the transistor. The drain-to-source effective distance (Lsd) is defined as the shortest distance between DVIR and SVIR when a transistor is under off-state bias condition.

FIG. 1(f) shows the cross-section views of the DVIR (163) and SVIR (161) of the MOS transistor in FIG. 1(e). Under off-state bias condition, the channel region (165) is also depleted due to influences of gate voltage. It would be difficult to view the boundaries of DVIR and SVIR if the depletion regions caused by gate voltage are also drawn in our figures. Therefore, the depletion regions causes by gate voltage are not drawn in FIG. 1(f) or in other figures of this patent application. For the prior art planar MOS transistor in this example, the drain diffusion region (113) are heavily doped so that the DVIR and SVIR of the transistor can expand into the channel region (165), as shown in FIG. 1(f), and the drain-to-source effective distance (Lsd) is shorter than effective channel length (Le). Significant leakage currents can pass through this lowered barrier, making it difficult to effectively turn off the MOS transistor. This problem is called the “Drain Voltage Induced Leakage” (DVIL) problem. The drain voltage induced leakage currents pass through channel areas that are deep in the substrate. It is proven that DVIL can be reduced significantly by reducing channel depth (Dg) to be less than one half of the effective channel length (Le/2). Reduction of channel depth (Dg) is therefore the most common prior art approach used to reduce DVIL.

“Semiconductor on insulator” (SOI) is one of the most common prior art method used to reduce DVIL. FIG. 2(a) shows a symbolic cross-section view of a SOI MOS transistor. The structure of this transistor is almost identical to that of the planar transistor in FIG. 1(e) except that its substrate is a thin layer of semiconductor (209) on a layer of insulator (201), as shown in FIG. 2(a). Because of this insulator layer (201), the channel depth (Dg) of the SOI transistor equals the thickness of the SOI layer (209). Since the depth of the drain diffusion regions (213) are also limited by the insulator (201), the effective drain depth (Dd) of the transistor is also equal to the thickness of the SOI layer (209). When Dg is smaller than one half of the effective channel length (Le/2) of the transistor, drain voltage induced leakage can be reduced significantly. SOI MOS transistors have been proven to function very well. However, the capability of manufacturing a thin SOI layer can become the limitation in reducing the channel length of transistors. It is therefore desirable to develop MOS transistors that do not completely rely on SOI to reduce DVIL.

The most popular prior art solutions for DVIL are multiple-gate MOS transistors. A multiple-gate MOS transistor, by definition, is a MOS transistor that comprises gates on multiple sides of a semiconductor substrate. FIG. 2(b) is a simplified diagram illustrating the three-dimensional structures of one example of a multiple-gate MOS transistor known as “FinFET”. The distinguishing structure of a FinFET is a thin slice of semiconductor “fin” (214) that forms the body of the device. This semiconductor fin (214) is formed above the field oxide so that a gate electrode (210) can wrap around three surfaces of the fin (214), as shown in FIGS. 2(b, c). The drain (217) and source (218) terminals of the FinFET are formed by heavily doped diffusion regions in the fin, as shown in FIG. 2(b). FIG. 2(c) is a simplified cross-section diagram illustrating the gate structures of the FinFET in FIG. 2(b). The interfaces between the gate electrode (210) and the semiconductor fin (214) on the two side surfaces (211, 212) of the fin form the gate interfaces of the FinFET. The top surface of the semiconductor body (214) of the transistor is typically separated from the gate electrode (210) by a thick insulator (219) so that the top surface is not active. Both the channel depth (Dg) and effective drain depth (Dd) of the FinFET are equal to the thickness of the FIN, as shown in FIG. 2(c). Since the semiconductor substrate (214) at the channel region of the FinFET is shared by two opposite gates (211, 212), when the thickness of the FIN is thinner than the effective channel length of the FinFET, the drain voltage induced leakage can be reduced significantly. This Wrap-around gate structure provides better electrical control over the channel and thus helps in overcoming short-channel effects. The channel depth of a FinFET can be twice the channel depth of a SOI transistor while achieving similar results in reducing DVIL. However, the capability of manufacturing a thin fin can become the limitation in reducing the channel length of transistors. FinFET also has higher parasitic capacitances relative to planar transistors. It is therefore desirable to develop MOS transistors that do not completely rely on building extremely thin semiconductor fins as the method to reduce DVIL.

### SUMMARY OF THE INVENTION

The primary objective of this invention is, therefore, to reduce drain voltage induced leakage (DVIL) of short channel MOS transistors. Another objective of this invention is to reduce the parasitic capacitances of short channel MOS transistors.

These and other objectives are achieved by reducing the effective drain depth (Dd) of MOS transistors.

While the novel features of the invention are set forth with particularly in the appended claims, the invention, both as to organization and content, will be better understood and appreciated, along with other objects and features thereof, from the following detailed description taken in conjunction with the drawings.

### BRIEF DESCRIPTION OF THE DRAWINGS

FIGS. 1(a-f) are symbolic cross-section diagrams illustrating the manufacturing procedures for a prior art MOS transistor;

FIG. 2(a) is a symbolic cross-section diagram showing the structures of a prior art SOI MOS transistor;

FIGS. 2(b-c) are symbolic diagrams showing the structures of a prior art FinFET;

FIGS. 3(a-l) are symbolic cross-section diagrams illustrating exemplary manufacturing procedures for a shallow drain MOS transistor of the present invention;

FIGS. 4(a-c) are symbolic cross-section diagrams illustrating exemplary manufacture procedures for another shallow drain MOS transistor of the present invention;

FIGS. 5(a-e) are symbolic cross-section diagrams illustrating exemplary manufacture procedures for a shallow drain MOS transistor of the present invention that has a deep drain diffusion region;

FIGS. 6(a-g) are symbolic cross-section diagrams illustrating exemplary manufacture procedures for a shallow drain MOS transistor of the present invention that has low capacitance source-drain areas;

FIGS. 7(a-f) are symbolic cross-section diagrams illustrating exemplary manufacture procedures for a shallow drain MOS transistor of the present invention that has low capacitance source-drain areas that are not completely self-aligned;

FIG. 8(a) is a symbolic cross-section diagram showing the structures of an exemplary shallow drain SOI MOS transistor; and

FIGS. 8(b) is symbolic diagram showing the structures of an exemplary shallow drain multiple-gate MOS transistor.

### DETAILED DESCRIPTION OF THE INVENTION

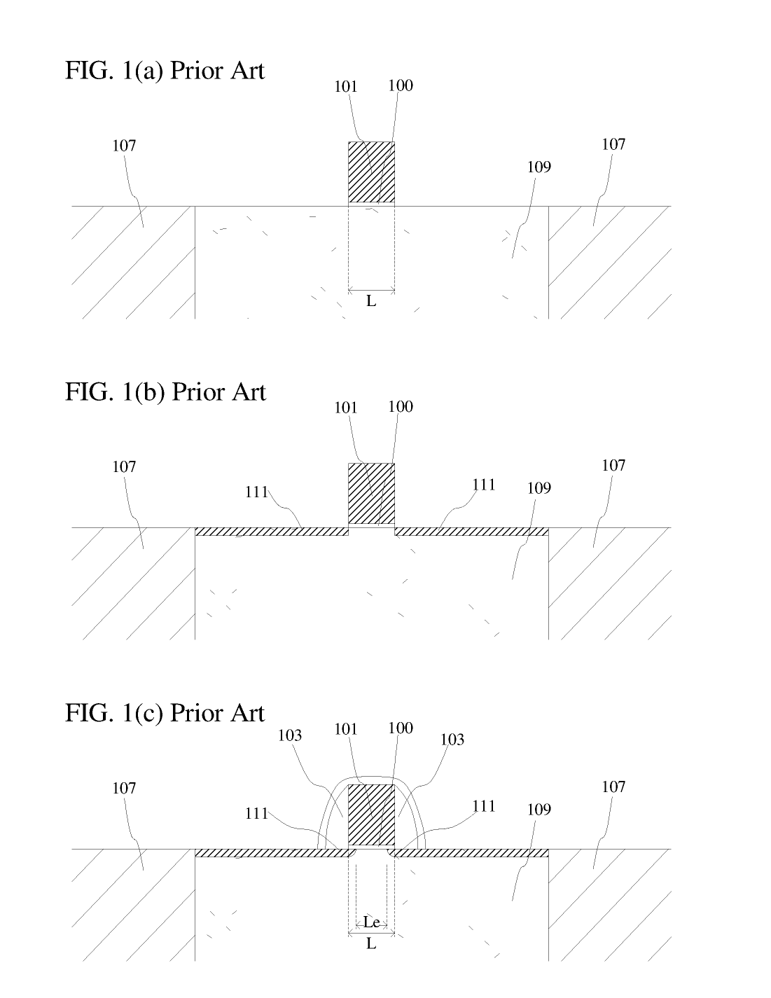

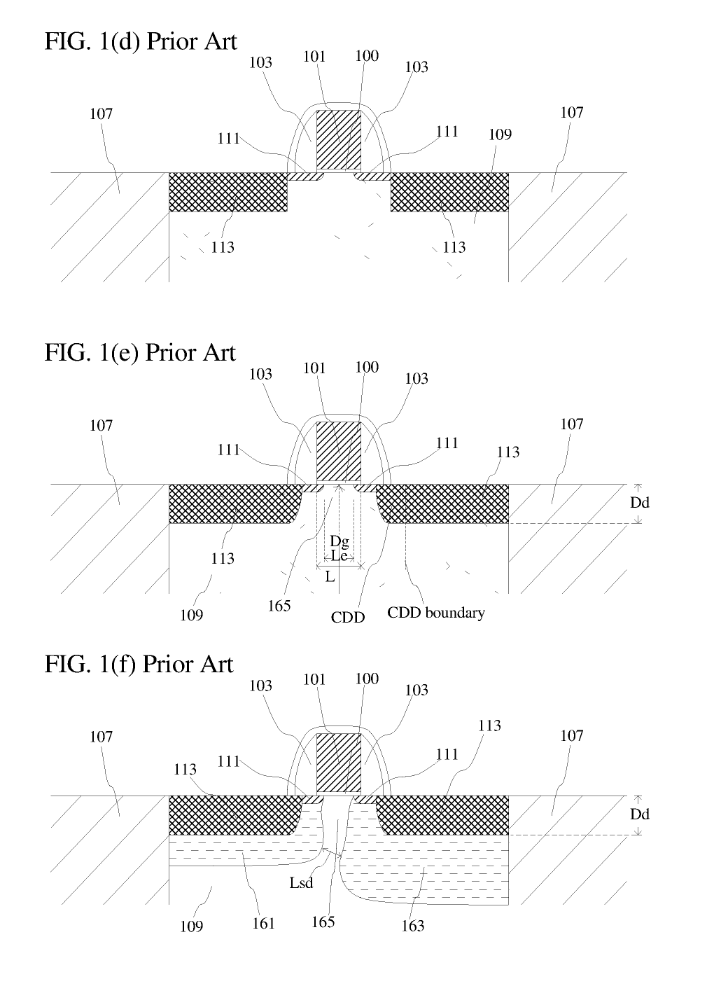

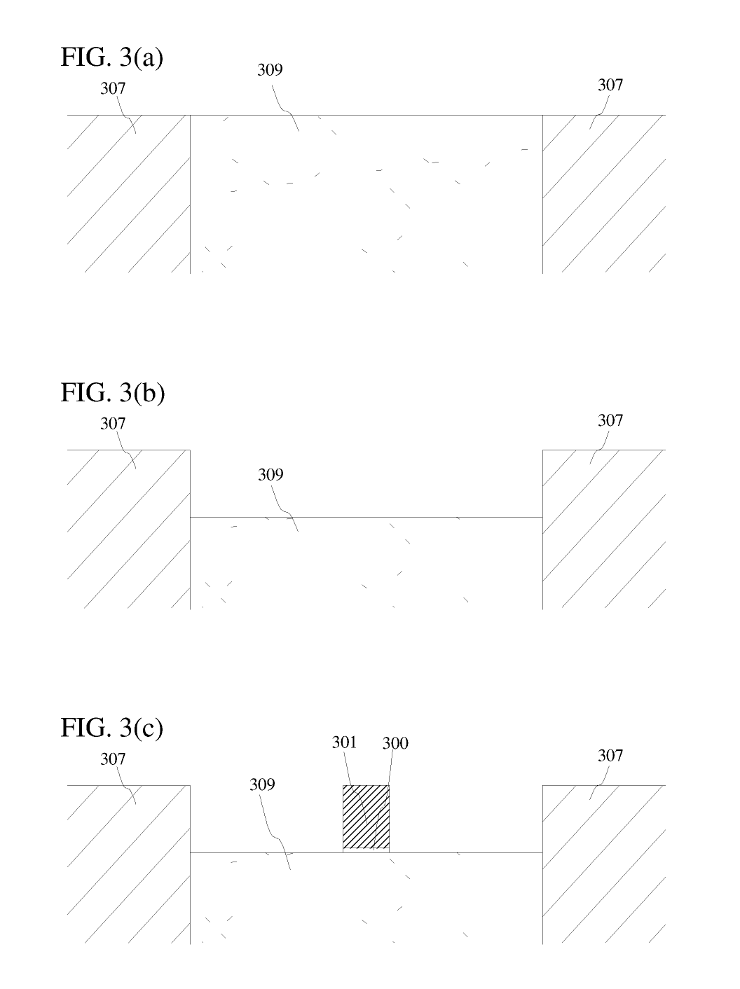

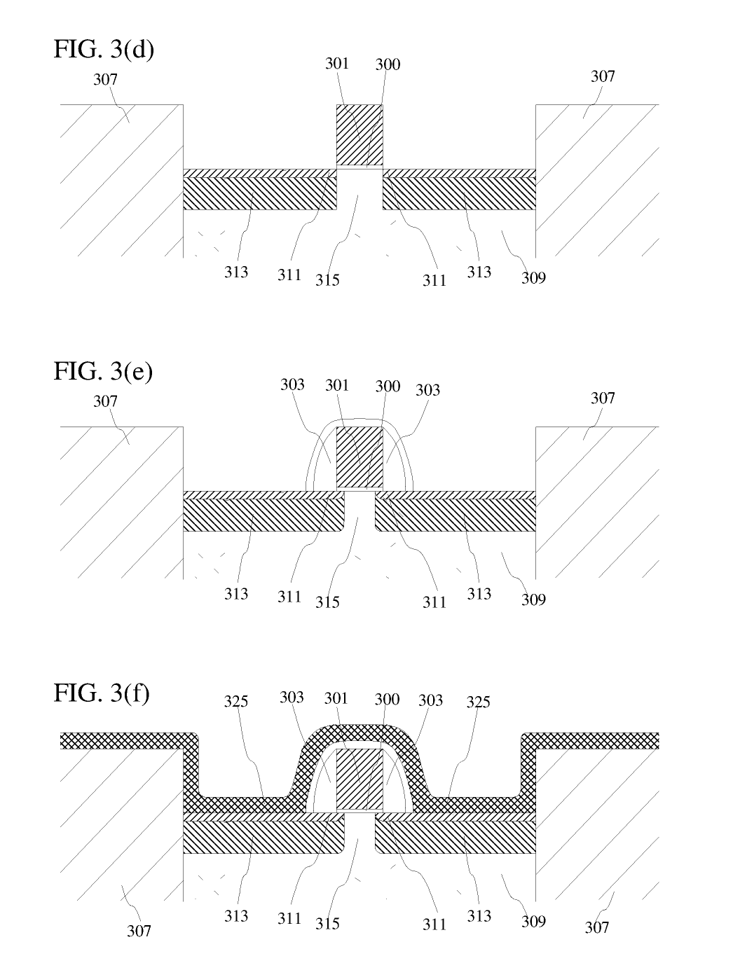

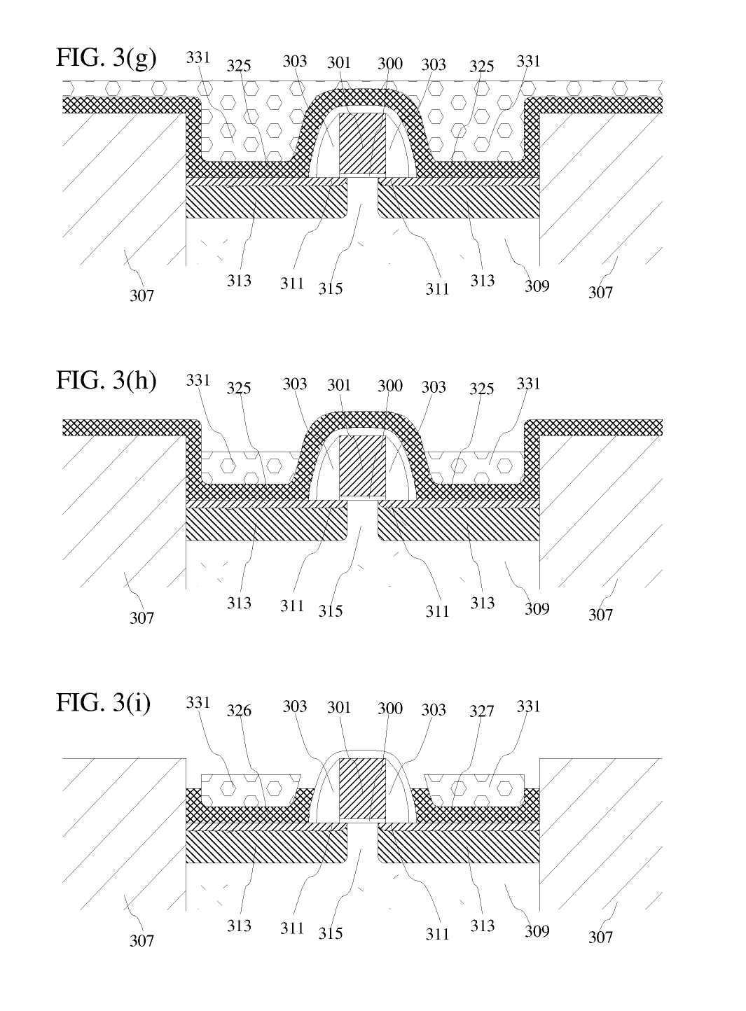

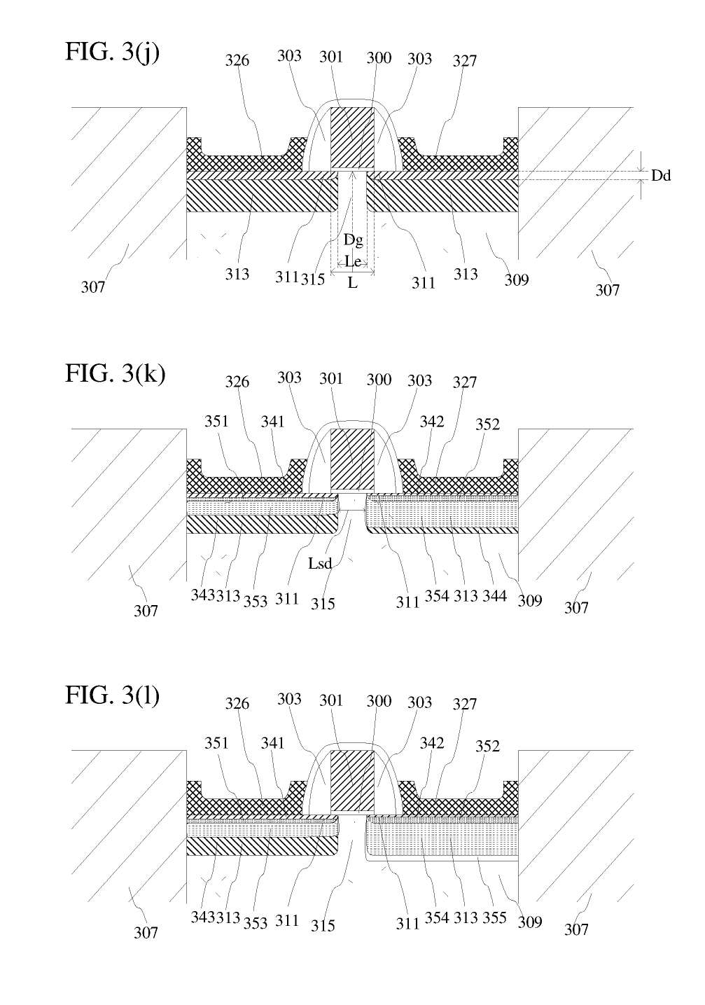

FIGS. 3(a-l) are symbolic cross-section diagrams illustrating exemplary manufacturing procedures for a shallow drain MOS transistor of the present invention. FIG. 3(a) is a symbolic cross-section diagram that shows an active area of a semiconductor substrate (309) surrounded by field insulators (307). Then the semiconductor substrate (309) is etched to a depth about the same as the height of transistor gate stack, as shown in FIG. 3(b). In the following steps, gate insulator (300) and gate conductor (301) are formed on the semiconductor substrate (309), as shown in FIG. 3(c). After gate formation, a shallow drain diffusion region (311) and a barrier diffusion region (313) are implanted under the source-drain areas, as shown in FIG. 3(d). Using the gate conductor (301) and the field insulators (307) as masking materials, implantations of these two layers (311, 313) are self-aligned. For n-channel MOS transistors, the shallow drain diffusion region (311) is n-type, while the barrier diffusion region (313) is p-type; for p-channel MOS transistors, the shallow drain diffusion region (311) is p-type, while the barrier diffusion region (313) is n-type. The channel area (315) under the gate insulator (300) is shielded from implants of those two layers (311, 313). The next step is to form gate spacers (303) as shown in FIG. 3(e). At this time, the shallow drain diffusion region (311) and the barrier diffusion region (313) expand into the area under gate insulator (300) due to heat treatments, as shown in FIG. 3(e). The next step is blank deposition of a drain conductor layer (325) as shown in FIG. 3(f). This drain conductor layer (325) supports low resistance connections with the drain diffusion region (311) and metal contacts; polysilicon is a material that can support those requirements, though other conductor materials also can be used for this purpose. The next step is blank deposition of a masking layer (331), as shown in FIG. 3(g). This masking layer (331) is selectively etched to expose unwanted area of the drain conductor layer (325), as shown in FIG. 3(h). Using the masking layer (331), the gate spacers (303), and the field insulators (307) as boundaries, the unwanted areas of the drain conductor layer (325) are etched away, and the remaining drain conductor layers (325) form a drain electrode conductor (327) and a source electrode conductor (326), as shown in FIG. 3(i). The masking layer (331) is then removed, as shown in FIG. 3(j). The MOS transistor shown in FIG. 3(j) has similar channel length (L), effective channel length (Le), and channel depth (Dg) as the prior art transistor in FIG. 1(e). The key difference is that the effective drain depth (Dd) of the transistor in FIG. 3(j) is equal to the depth of the shallow drain diffusion region (311), which is much shallower than the effective drain depth of the prior art transistor in FIG. 1(e) because there is no heavily doped drain diffusion (113) deposited into the substrate (309).

FIG. 3(k) is a symbolic cross-section diagram illustrating the “Drain Voltage Influenced Region” (DVIR), and the “Source Voltage Influenced Region” (SVIR) of the shallow drain transistor in FIG. 3(j). The voltage applied on the source electrode conductor (326) caused a depletion region (351) to form in the shallow drain diffusion region (311) under the source electrode (341), and a depletion region (353) to form in the barrier diffusion region (313) under the source electrode (343), as shown in FIG. 3(k). The SVIR of the transistor is therefore a combination of those two depletion regions (351, 353). When the effective drain depth (Dd) of the transistor is shallow, for example, Dd<L/4, and when the barrier diffusion region (313) is strong enough to shield the electrical fields generated by the voltage on the source electrode conductor (326), as shown in FIG. 3(k), the area where SVIR expands into the channel region (315) of the shallow drain transistor is much smaller than that of the prior art MOS transistor in FIG. 1(f).

The voltage applied on the drain electrode conductor (327) causes a depletion region (352) to form in the shallow drain diffusion region (311) under the drain electrode (342), and a depletion region (354) to form in the barrier diffusion region (313) under the drain electrode (344), as shown in FIG. 3(k). The DVIR of the transistor is a combination of the two depletion regions (352, 354) under the drain terminal. When the effective drain depth (Dd) of the transistor is shallow, for example, Dd<L/4, and when the barrier diffusion region (313) is strong enough to shield the electrical fields generated by the voltage on the drain electrode conductor (327), as shown in FIG. 3(k), the area where DVIR expands into the channel area (315) of the shallow drain transistor is much smaller than that of the prior art MOS transistor in FIG. 1(f). The effective source-to-drain distance (Lsd) of a shallow drain transistor is close to the effective channel length (Le) of the transistor, as shown in FIG. 3(k). Therefore, the channel region (315) of the transistor is effectively controlled by the gate voltage, and the drain voltage induced leakage (DVIL) can be reduced significantly.

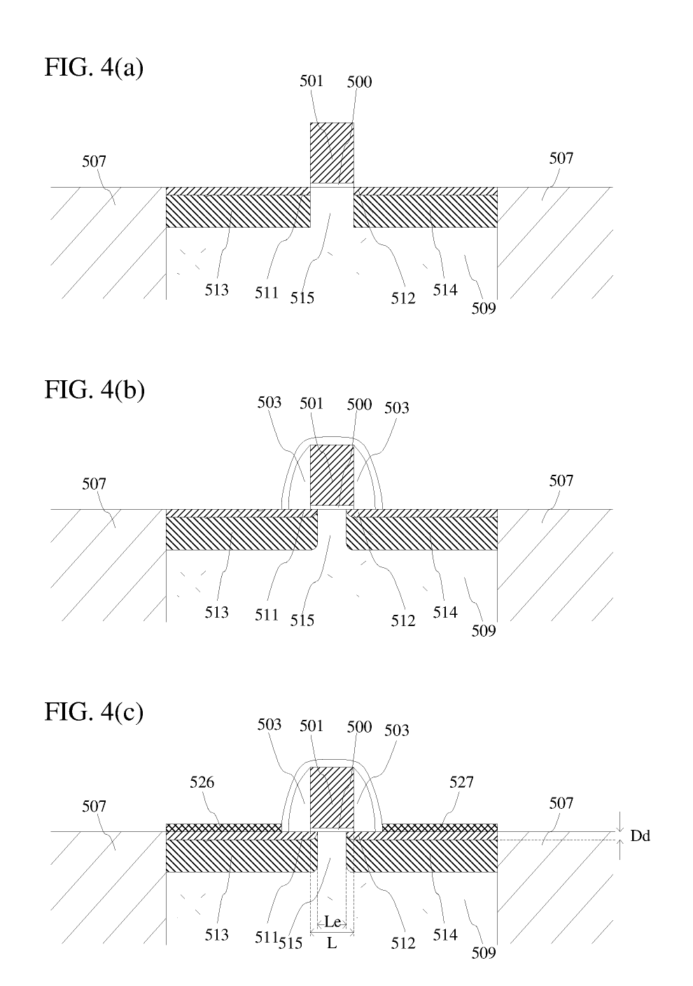

While specific embodiments of the invention have been illustrated and described herein, it is realized that other modifications and changes will occur to those skilled in the art. It is therefore to be understood that the scope of the present invention is not limited by specific examples. For the example in FIG. 3(k), the barrier diffusion region (313) under the drain electrode conductor (327) is strong enough that only part of it is depleted. For some cases, the barrier diffusion region (313) under the drain electrode conductor (327) can be fully depleted so that DVIR can expand into areas (355) in the semiconductor substrate (309), as shown in FIG. 3(l). Even when the barrier diffusion region (313) is completely depleted, it still helps to reduce DVIL. For another example, FIGS. 4(a-c) show exemplary manufacture procedures to build shallow drain transistors of the present invention using fewer processing steps than those shown in FIGS. 3(a-l).

FIG. 4(a) is a symbolic cross-section diagram that shows structures similar to those in FIG. 3(e), except the semiconductor substrate (509) is at the same level as the field insulators (507). At this stage, gate insulator (500) and gate conductor (501) are formed on the semiconductor substrate (509), while shallow drain diffusion regions (511, 512) and barrier diffusion regions (513, 514) are formed under the source-drain areas by self-aligned ion implantation using the gate conductor (501) and the field insulators (507) as masking structures, as shown in FIG. 4(a). For n-channel MOS transistors, the shallow drain diffusion regions (511, 512) are n-type, while the barrier diffusion regions (513, 514) are p-type; for p-channel MOS transistors, the shallow drain diffusion regions (511, 512) are p-type, while the barrier diffusion regions (513, 514) are n-type. The next step is to form gate spacers (503) as shown in FIG. 4(b). At this time, the shallow drain diffusion regions (511, 512) and the barrier diffusion regions (513, 514) expand into the channel region (515) due to heat treatments, as shown in FIG. 4(b). When the surface doping density of the shallow drain diffusion regions (511, 512) is high enough, self-aligned formation of source electrode conductor (526) and drain electrode conductor (527) can be achieved by selective chemical reactions on the exposed semiconductor areas using conductor materials such as silicide, as shown in FIG. 4(c).

The MOS transistor shown in FIG. 4(c) has the same channel length (L), effective channel length (Le), channel depth (Dg), and effective drain depth (Dd) as those parameters of the transistor in FIG. 3(k). Therefore, the channel region (515) of the transistor is effectively controlled by the gate voltage, and the drain voltage induced leakage (DVIL) can be reduced significantly.

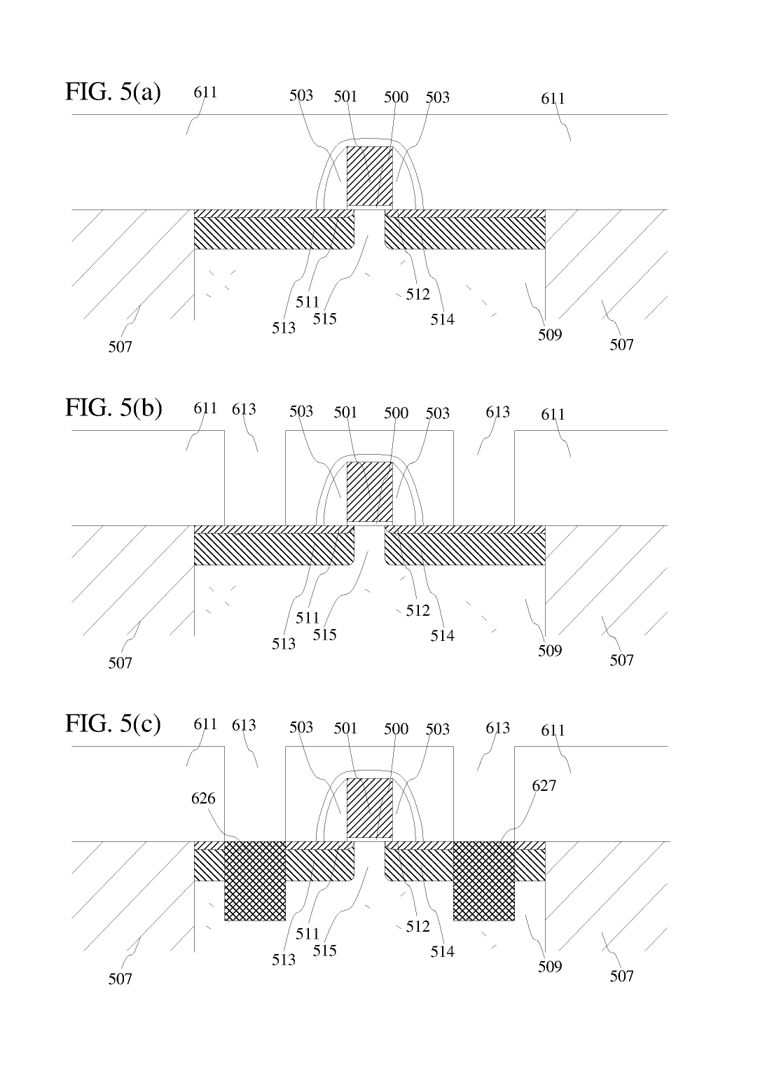

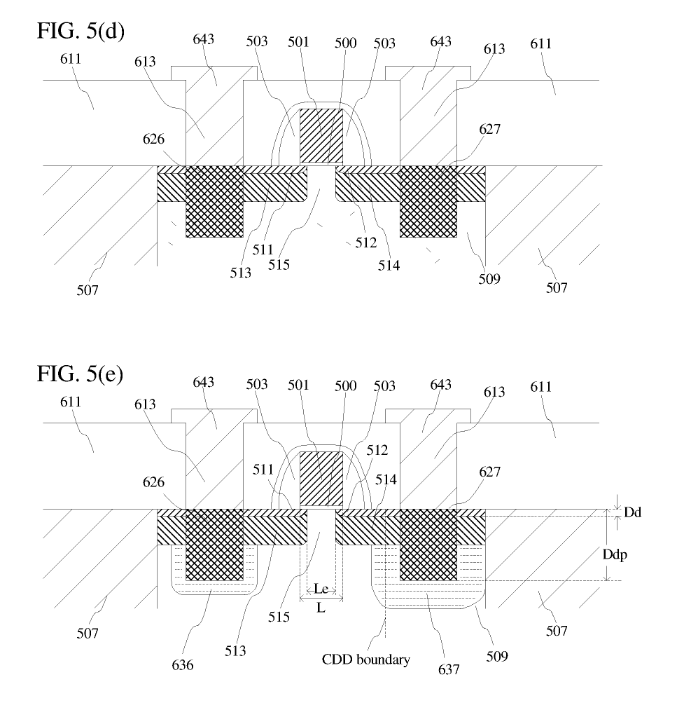

While specific embodiments of the invention have been illustrated and described herein, it is realized that other modifications and changes will occur to those skilled in the art. It is therefore to be understood that the scope of the present invention is not limited by specific examples. For example, the shallow drain transistors in FIG. 3(k) and in FIG. 4(c) do not have heavily doped drain diffusion regions, while a shallow drain transistor of the present invention can have heavily doped drain diffusion regions, as illustrated by the example in FIGS. 5(a-e).

Starting from the structures shown in FIG. 4(b), a layer of dielectric material (611) is deposited on top of the wafer, as shown in FIG. 5(a). Contact holes (613) are opened on the source-drain areas through the dielectric material (611), as shown in FIG. 5(b). Using the dielectric material (611) as a masking layer, heavily doped drain diffusion (626, 627) can be implanted into the semiconductor substrate (509) in regions under the contact holes (613), as shown in FIG. 5(c). Then metal contacts (643) are formed to provide electrical connections to the source and drain terminals of the transistor, as shown in FIG. 5(d). The depth (Ddp) of the heavily doped drain diffusion regions (626, 627) is much deeper than the depth (Dd) of the shallow drain diffusion regions (511, 512) so that the depletion regions (636, 637) around the heavily doped drain diffusion regions (626, 627) can expand deeply into the semiconductor substrate (509), as shown in FIG. 5(e). Those depletion regions (636, 637) caused by heavily doped drain diffusion regions (626, 627) will not cause drain voltage induced leakage current because they are far away from the channel region (515). For the example shown in FIG. 5(e), the effective drain depth (Dd) of the transistor equals the depth of the shallow drain diffusion region (511, 512) because the heavily doped drain diffusion regions (526, 527) are more than one channel length (L) away from the channel region (502). The CDD boundary is marked by a dash line in FIG. 5(e). By definition, the MOS transistor in FIG. 5(e) is a shallow drain transistor of the present invention because the heavily doped drain diffusion regions (526, 527) are out of the CDD boundary.

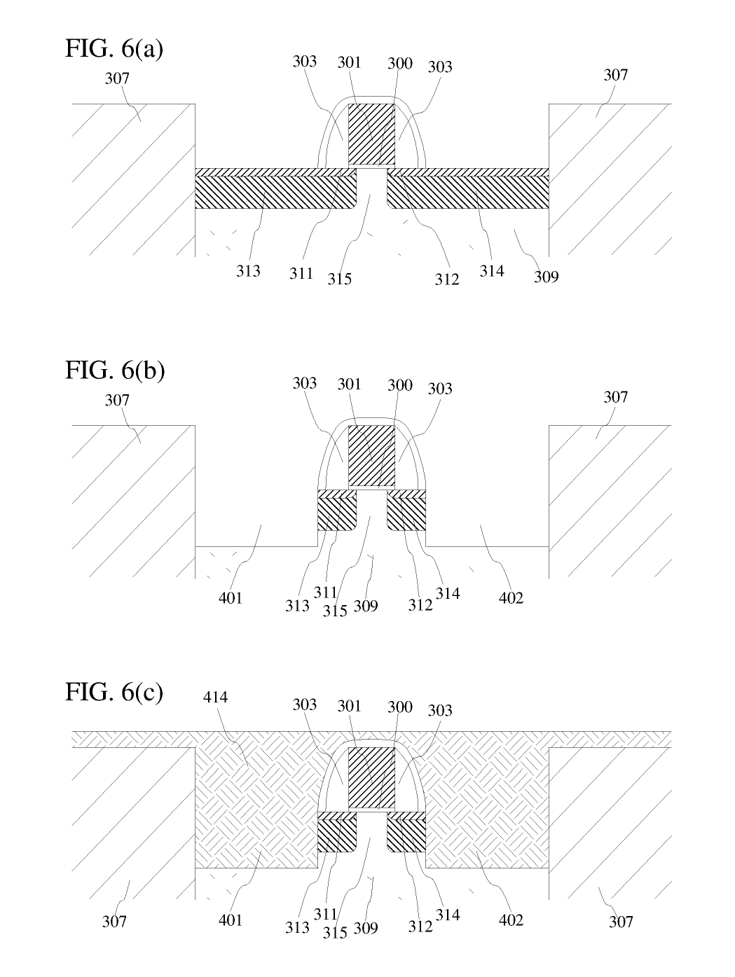

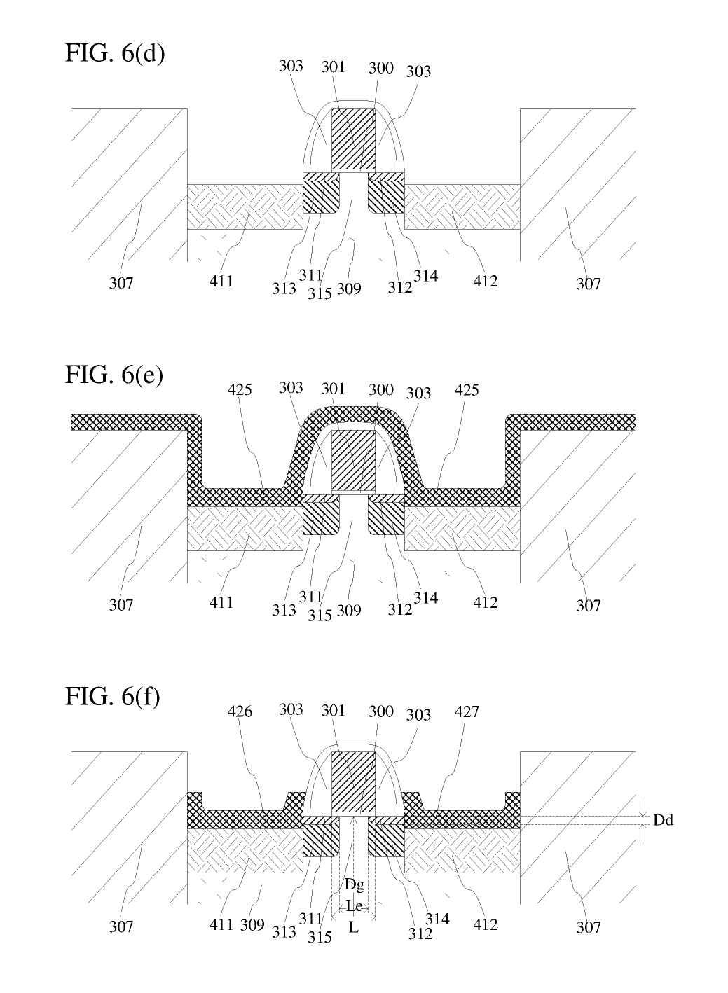

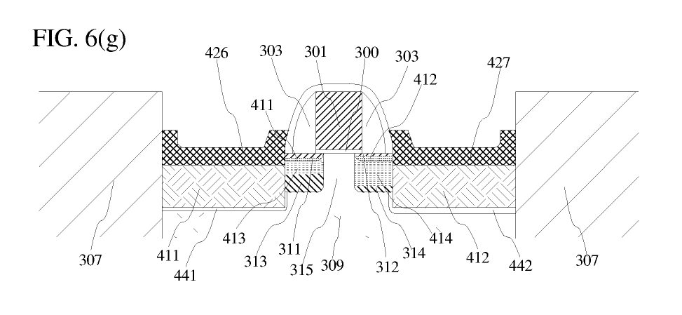

While specific embodiments of the invention have been illustrated and described herein, it is realized that other modifications and changes will occur to those skilled in the art. It is therefore to be understood that the scope of the present invention is not limited by specific examples. For example, the shallow drain transistors in previous examples all have diffusion regions in the semiconductor substrate under their source and drain areas, while the example illustrated in FIGS. 6(a-g) has an insulator layer under source and drain areas.

Following the same manufacturing steps in FIGS. 3(a-e), the structures in FIG. 6(a) is the same as the structures in FIG. 3(e). The next step is to etch trenches (401, 402) under the source-drain areas, as shown in FIG. 6(b). Then these trenches (401, 402) are filled with an insulator layer (414), as shown in FIG. 6(c). This insulator layer (414) is etched to a depth that can expose the shallow drain diffusion region (311, 312), as shown in FIG. 6(d); the remaining insulator materials (414) in the trenches (401, 402) form the source insulator barrier (411) and drain insulator barrier (412), as shown in FIG. 6(d). The next step is deposition of a drain conductor layer (425), as shown in FIG. 6(e). The structures of the drain conductor layer (425) in FIG. 6(e) are similar to the structures of the drain conductor layer (325) in FIG. 3(f). Therefore, using similar self-aligned manufacturing procedures shown in FIGS. 3(g-j), the drain conductor layer (425) can be patterned into the source electrode conductor (426) and the drain electrode conductor (427), as shown in FIG. 6(f). The MOS transistor shown in FIG. 6(f) has the same structures as the MOS transistor in FIG. 3(j), except that the areas under the source electrode conductor (426) and the drain electrode conductor (427) are insulator barriers (411, 412) instead of semiconductor substrate. The MOS transistor shown in FIG. 6(f) has the same channel length (L), effective channel length (Le), and channel depth (Dg) as the MOS transistor in FIG. 3(j). The depth of the diffusion region under the drain electrode conductor (427) is zero because the drain electrode conductor is deposited on top of an insulator barrier (412) instead of a semiconductor substrate. Therefore, the effective drain depth (Dd) of this transistor is the same as the depth of the shallow drain diffusion region (312), as shown in FIG. 6(f). At off-state bias condition, the “Drain Voltage Influenced Region” (DVIR), and the “Source Voltage Influenced Region” (SVIR) at areas under the gate spacers (303) are similar to those of the shallow drain transistor in FIG. 3(j). The voltage on the source electrode conductor (426) induces a depletion region (441) under the source insulator barrier (411), and the voltage on the drain electrode conductor (427) induces a depletion region (442) under the drain insulator barrier (412), as shown in FIG. 6(g). When the effective drain depth (Dd) of the transistor is shallow, for example, Dd<L/4, and when the insulator barriers (411, 412) are thick enough to significantly reduce the electrical fields generated by the source and drain voltages, the shallow drain transistor in FIG. 6(g) is as effective as the shallow drain transistor in FIG. 3(k) in reducing DVIL.

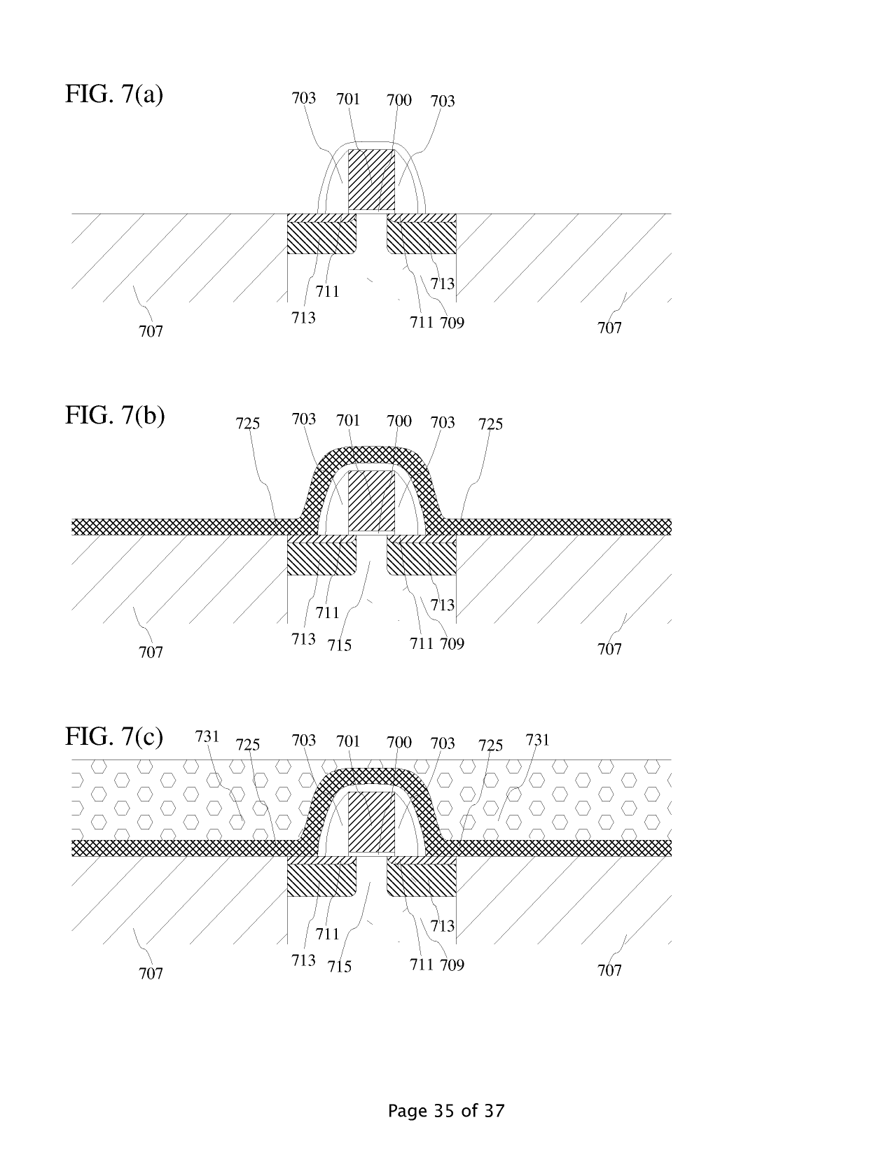

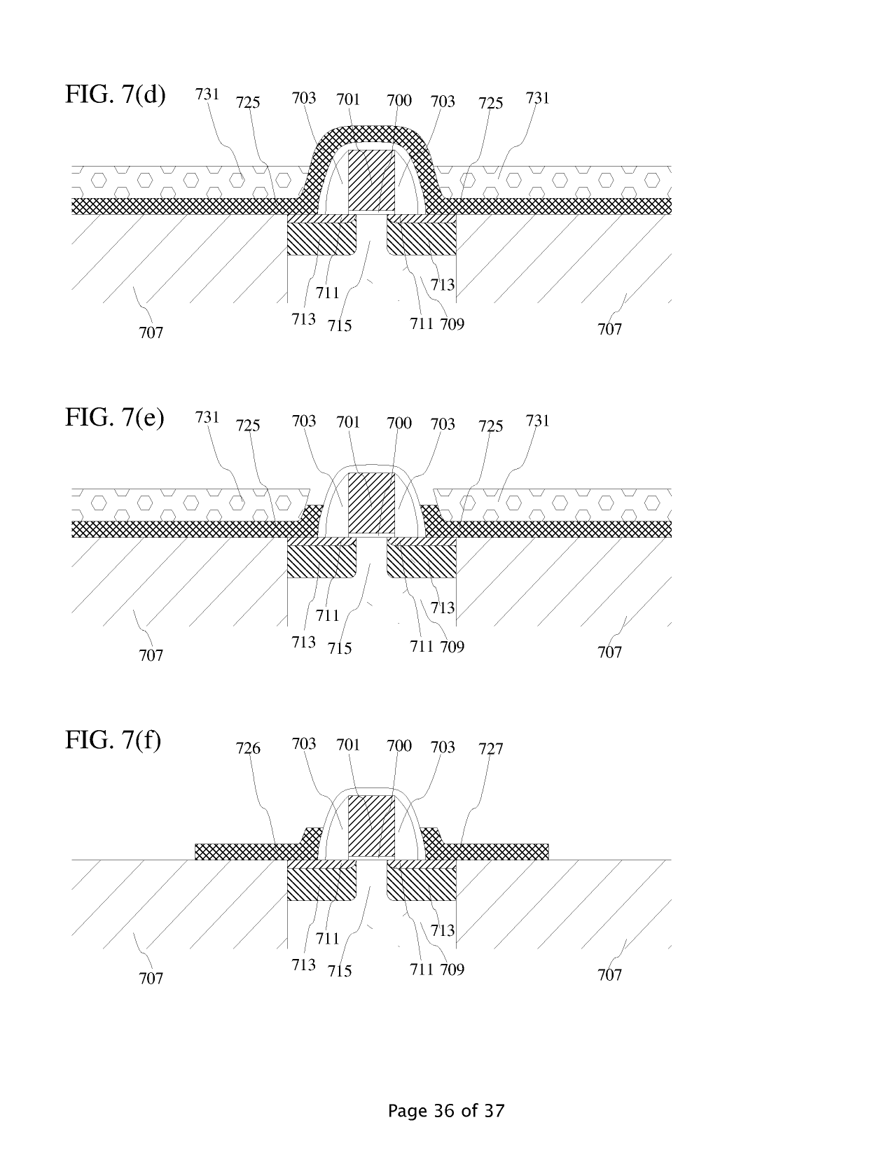

While specific embodiments of the invention have been illustrated and described herein, it is realized that other modifications and changes will occur to those skilled in the art. It is therefore to be understood that the scope of the present invention is not limited by specific examples. For example, the shallow drain transistor in previous exampled reduces source-drain parasitic capacitances by forming insulator barriers (411, 412) under source-drain areas using self-aligned manufacture procedures. FIGS. 7(a-f) are symbolic cross-section diagrams illustrating exemplary manufacturing procedures for a shallow drain MOS transistor of the present invention that has low capacitance source-drain areas that are not completely self-aligned.

The structures in FIG. 7(a) are the same as the structures in FIG. 4(b) except the field insulators (707) in FIG. 7(a) cover more areas than the field insulators (507) in FIG. 4(b). At this step, the gate insulator (700), gate conductor (701), and gate spacers (703) are formed on the surface of the semiconductor substrate (709), while the shallow drain diffusion regions (711) and the barrier diffusion regions (713) have been implanted into the semiconductor substrate (709), as shown in FIG. 7(a). The next step is deposition of the drain conductor layer (725) as shown in FIG. 7(b). Then a masking layer (731) is deposited, as shown in FIG. 7(c). This masking layer (731) is etched to expose the drain conductor layer (725) near the gate spacers (703), as shown in FIG. 7(d). Using the masking layer (731) and the gate spacers (703) as boundaries, the drain conductor layer (725) near the gate spacers (703) are etched away, as shown in FIG. 7(e). After the masking layer (731) is removed, an addition masking step is used to define the source electrode conductor (726) and the drain electrode conductor (727), as shown in FIG. 7(f).

The properties of the shallow drain transistor in FIG. 7(f) are nearly the same as the properties of the shallow drain transistor in FIG. 6(f), while manufacturing steps are simplified. One additional masking step is used to define the source electrode conductor (726) and the drain electrode conductor (727), but this masking step allows the drain conductor layer (725) to be used as an interconnection layer, which can be very useful for electrical components such as static random access memory cells.

While specific embodiments of the invention have been illustrated and described herein, it is realized that other modifications and changes will occur to those skilled in the art. It is therefore to be understood that the scope of the present invention is not limited by specific examples. For example, the channel depths (Dg) of the shallow drain transistors in the above examples are all much larger than the channel length of the transistor, while shallow drain is also desirable for MOS transistors with shallow channel depth such as SOI transistors and multiple-gate transistors.

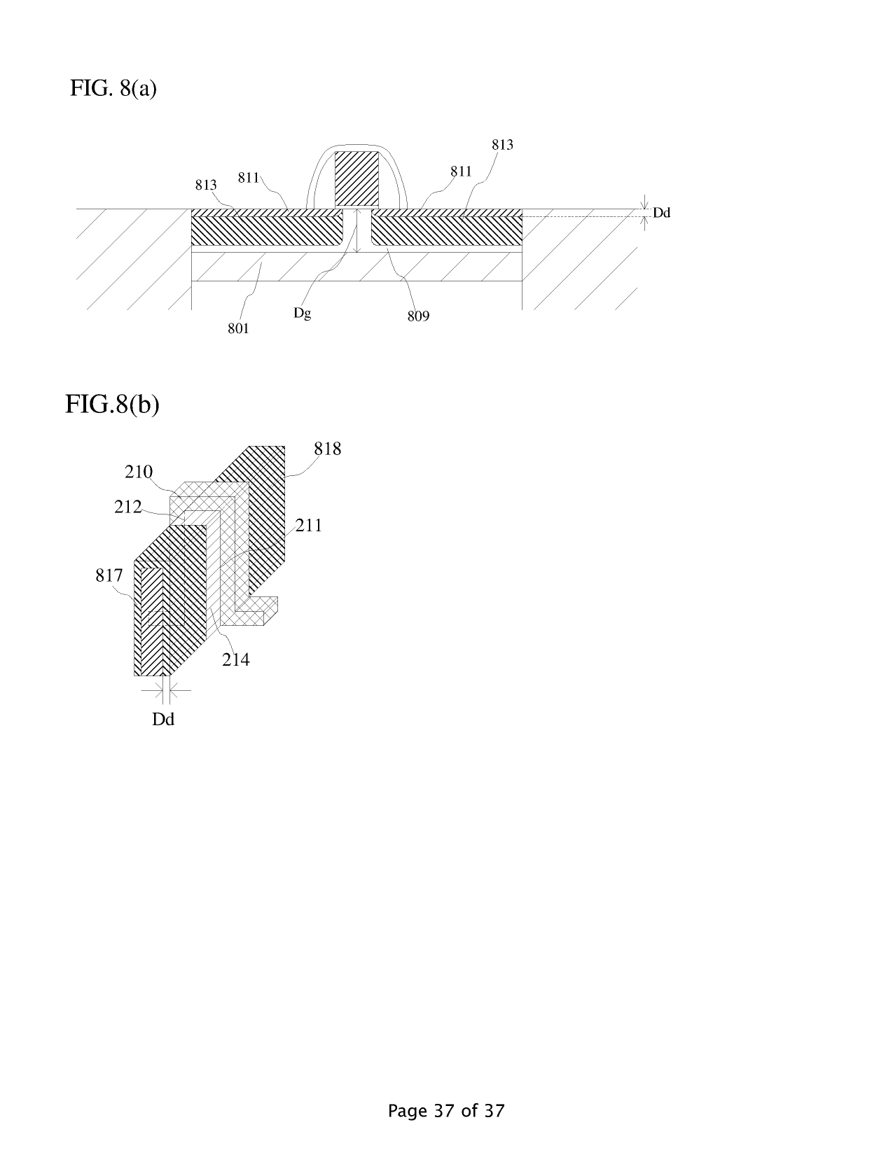

FIG. 8(a) is a symbolic cross-section diagram showing an SOI transistor that has a shallow drain diffusion region (811) and barrier diffusion region (813). This SOI transistor is built on a semiconductor substrate (809) that is on top of an insulator layer (801) so that its channel depth (Dg) equals the thickness of the SOI layer (809). On the other hand, this transistor is also a shallow drain transistor because its effective drain depth (Dd) equals the depth of the shallow drain diffusion region (811), as shown in FIG. 8(a). Shallow drain SOI transistors can achieve better control of the channel region than prior art SOI transistors. The thickness of SOI does not need to be small than L/2 for a shallow drain SOI transistor, which significantly improves manufacturability.

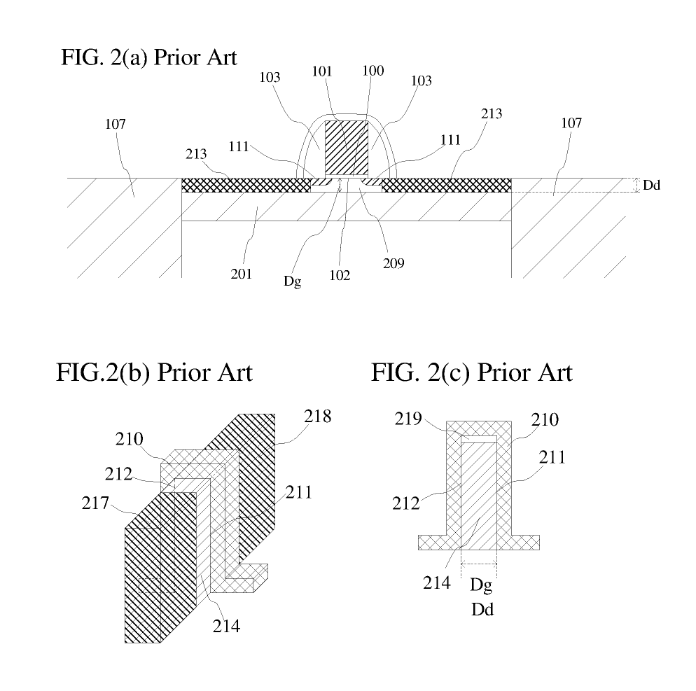

FIG. 8(b) is a symbolic diagram showing three-dimensional structures of a shallow drain FinFET of the present invention. The structures of this FinFET are identical to those of the FinFET in FIG. 2(b) except it has shallow drain doping (817, 818). The effective drain depth (Dd) of this FinFET is much smaller than the thickness of its fin (214), as shown in FIG. 8(b). Therefore, this FinFET is a shallow drain transistor. Shallow drain multiple-gate transistors can achieve better control of the channel region than prior art multiple-gate transistors. The thickness of the fin for a shallow drain multiple-gate transistor does not need to be smaller than the channel length, which significantly improves manufacturability.

While specific embodiments of the invention have been illustrated and described herein, it is realized that other modifications and changes will occur to those skilled in the art. It is therefore to be understood that the scope of the present invention is not limited by specific examples. A shallow drain MOS transistor of the present invention comprises a gate insulator on the surface of a semiconductor substrate, and a drain terminal that has an effective channel depth (Dd) that is shorter than one quarter of the channel length (L) of the MOS transistor, and Dd is also shorter than one half of the channel depth (Dg) of the MOS transistor; the channel length (L) determined by the gate insulator is shorter than 60 nanometers (nm), shorter than 30 nm, or shorter than 20 nm. For one type of embodiments, the maximum depth of all the drain diffusion regions or drain diffusion regions in the semiconductor substrate of a shallow drain transistor is shorter than one quarter of the channel length of the MOS transistor. For other type of embodiments, a shallow drain MOS transistor can have deep drain diffusion regions that are far away from the channel region. It is typically desirable to have a barrier diffusion region under the critical drain diffusion region of a shallow drain MOS transistor, where the doping type of the barrier diffusion region is opposite to the doping type of the drain diffusion region of the MOS transistor. An insulator layer under the drain electrode conductor of the transistor can be used to reduce parasitic capacitance of drain terminal. A polysilicon layer deposited on top of the drain diffusion region in the semiconductor substrate can be used to provide low impedance electrical connection to metal contacts. A shallow drain MOS transistor of the present invention can be a planar transistor, a SOI transistor, a multiple-gate transistor, or a transistor with other types of structures.

While specific embodiments of the invention have been illustrated and described herein, it is realized that other modifications and changes will occur to those skilled in the art. It is therefore to be understood that the appended claims are intended to cover all modifications and changes as fall within the true spirit and scope of the invention.

1. A Metal-Oxide-Semiconductor (MOS) transistor comprises:
a gate insulator on the surface of a semiconductor substrate, where the channel length (L) determined by the gate insulator is shorter than 60 nanometers;
a drain terminal that has an effective drain depth (Dd) that is shorter than one quarter of the channel length (L) of the MOS transistor, and Dd is also shorter than one half of the channel depth (Dg) of the MOS transistor;
where the channel depth (Dg) is the depth of the semiconductor substrate under the gate insulator of the MOS transistor, and the effective drain depth (Dd) is the maximum depth of the critical drain diffusion region of the MOS transistor, where the critical drain diffusion region includes the drain diffusion region or drain diffusion regions in the semiconductor substrate that are no more than one channel length away from the edge of the channel region of the MOS transistor.

2. The channel length of the MOS transistor in claim 1 is shorter than 30 nanometers.

3. The channel length of the MOS transistor in claim 1 is shorter than 20 nanometers.

4. The maximum depth of all the drain diffusion region or drain diffusion regions in the semiconductor substrate of the MOS transistor in claim 1 is shorter than one quarter of the channel length of the MOS transistor.

5. The MOS transistor in claim 1 comprise barrier diffusion region under the critical drain diffusion region of the transistor, where the doping type of the barrier diffusion region is opposite to the doping type of the drain diffusion region of the MOS transistor.

6. The MOS transistor in claim 1 comprises an insulator layer under the drain electrode conductor of the MOS transistor. cm 7. The MOS transistor in claim 1 comprises a polysilicon layer deposited on top of the drain diffusion region in the semiconductor substrate.

8. The MOS transistor in claim 1 is a planar MOS transistor.

9. The MOS transistor in claim 1 is a multiple-gate MOS transistor.

10. The semiconductor substrate of the MOS transistor in claim 1 is a semiconductor-on-insulator (SOI) substrate.

11. A method for manufacturing a Metal-Oxide-Semiconductor (MOS) transistor comprising the steps of:
Manufacturing a gate insulator on the surface of a semiconductor substrate, where the channel length (L) determined by the gate insulator is shorter than 60 nanometers;
Manufacturing a drain terminal of the MOS transistor that has an effective channel depth (Dd) that is shorter than one quarter of the channel length (L) of the MOS transistor, and Dd is also shorter than one half of the channel depth (Dg) of the MOS transistor.

12. The method for manufacturing a Metal-Oxide-Semiconductor in claim 11 comprises a step of manufacturing a gate insulator on the surface of a semiconductor substrate where the channel length (L) determined by the gate insulator is shorter than 30 nanometers.

13. The method for manufacturing a Metal-Oxide-Semiconductor in claim 11 comprises a step of manufacturing a gate insulator on the surface of a semiconductor substrate where the channel length (L) determined by the gate insulator is shorter than 20 nanometers.

14. The method for manufacturing a Metal-Oxide-Semiconductor in claim 11 comprises a step of manufacturing drain diffusion region or drain diffusion regions where the maximum depth of all the drain diffusion region or drain diffusion regions in the semiconductor substrate of the MOS transistor is shorter than one quarter of the channel length of the MOS transistor.

15. The method for manufacturing a Metal-Oxide-Semiconductor in claim 11 comprising a step of manufacturing barrier diffusion region under the critical drain diffusion region of the transistor, where the doping type of the barrier diffusion region is opposite to the doping type of the drain diffusion region of the MOS transistor.

16. The method for manufacturing a Metal-Oxide-Semiconductor in claim 11 comprising a step of manufacturing an insulator layer under the drain electrode conductor of the MOS transistor.

17. The method for manufacturing a Metal-Oxide-Semiconductor in claim 11 comprising a step of forming a polysilicon layer deposited on top of the drain diffusion region in the semiconductor substrate.

18. The method for manufacturing a Metal-Oxide-Semiconductor in claim 11 comprises a step of forming gate insulator on a planar semiconductor substrate.

19. The method for manufacturing a Metal-Oxide-Semiconductor in claim 11 comprises a step of forming gate insulator for a multiple-gate MOS transistor.

20. The method for manufacturing a Metal-Oxide-Semiconductor in claim 11 comprises a step of forming gate insulator on a semiconductor-on-insulator (SOI) substrate.
